(19) United States
(12) Patent Application Publication
(10) Pub. No.: US 2024/0264211 A1
(43) Pub. Date: Aug. 8, 2024

(54) MOTOR DRIVE DEVICE THAT CALCULATES INSULATION RESISTANCE VALUE OF MOTOR

(71) Applicant: Fanuc Corporation, Minamitsuru-gun, Yamanashi (JP)

(72) Inventor: Taku Sasaki, Minamitsuru-gun, Yamanashi (JP)

(73) Assignee: Fanuc Corporation, Minamitsuru-gun, Yamanashi (JP)

(21) Appl. No.: 18/566,785

(22) PCT Filed: Jun. 16, 2021
(86) PCT No.: PCT/JP2021/022880

§ 371 Date: Dec. 4, 2023

(51) Int. Cl. G01R 27/02; G01R 31/34; H02P 23/14; H02P 27/06

(52) U.S. Cl. CPC G01R 27/025; G01R 31/343; H02P 23/14; H02P 27/06

(57) ABSTRACT

This motor drive device includes an insulation resistance value detection unit for calculating an insulation resistance value of a motor on the basis of: a measurement value of voltage of a smoothing capacitor provided between a rectifier circuit and an inverter; a measurement value of inter-terminal voltage of a measurement resistor; a measurement error calculated on the basis of an estimated value and the measurement value of the inter-terminal voltage of the measurement resistor in the state of being connected to an external DC power supply; and a resistance value of the measurement resistor.

### CROSS REFERENCE TO RELATED APPLICATIONS

This is the U.S. National Phase application of PCT/JP2021/022880, filed Jun. 16, 2021, the disclosure of this application being incorporated herein by reference in its entirety for all purposes.

### FIELD OF THE INVENTION

The present invention relates to a motor drive device configured to calculate an insulation resistance value of a motor.

### BACKGROUND OF THE INVENTION

In a servomotor provided in a machine tool or the like, a resistance value of an insulation resistor (insulation resistance value) of a motor coil (winding) relative to the ground decreases over time due to intrusion of oil or the like. When the insulation resistance value of the motor coil decreases, the leak current will flow through a closed circuit consisting of a motor, a motor drive device and the ground. Since the leak current flows through the motor drive device in addition to electric current for driving the motor, a servo amplifier may perform an overcurrent detection operation, or a breaker provided in an input stage may trip. As a result, the machine tool provided with the motor may undergo an emergency shut down. When such an emergency shutdown occurs, the machine tool may be stopped over a long period of time for investigation into the cause, which reduces efficiency. Therefore, a task of measuring the insulation resistance value of the motor is indispensable in operating the motor drive device.

For example, there is known a method of detecting deterioration of an insulation resistance of a motor driven by a motor drive device including: a power supply unit configured to rectify, with a rectifier circuit, electrical power supplied from an AC power supply via a switch and smooth the electrical power with a capacitor; and a motor drive amplifier configured to convert a DC voltage from the power supply unit into an AC voltage to drive the motor, wherein after the switch is turned off and operation of the motor is stopped, one end of the capacitor is connected to the ground while the other end of the capacitor is connected to a motor coil, and deterioration of the insulation resistance of the motor is detected by detecting an electric current flowing through a closed circuit consisting of the capacitor, the motor coil, and the ground (for example, see PTL 1).

For example, there is known a motor drive device having a function of detecting a failure of an insulation resistance deterioration detection unit of a motor, the motor drive device including: a power supply unit configured to rectify an AC voltage supplied from an AC power supply via a switch into a DC voltage with a rectifier circuit and smooth the rectified DC voltage with a capacitor; a motor drive amplifier unit configured to convert the DC voltage from the power supply unit into an AC voltage using switching elements in an upper arm and a lower arm to drive the motor; a power supply voltage measurement unit configured to measure a voltage of the power supply unit; an insulation resistance deterioration detection unit including a contact part for connecting one end of the capacitor to the ground and an electric current detection unit placed between the other end of the capacitor and a motor coil, the insulation resistance deterioration detection unit configured to detect whether or not the insulation resistance of the motor has deteriorated in a condition where the switch is set in an OFF state and the contact part is set in an ON state, using the electric current detection unit, on the basis of a detection signal obtained from a closed circuit consisting of the contact part, the capacitor, and the motor coil, and the ground; and a failure detection unit configured to detect whether or not the insulation resistance deterioration detection unit has failed, in a condition where the contact part is set from the ON state to an OFF state and the switching elements of the upper arm or the lower arm of the motor drive amplifier unit are switched as desired, on the basis of the detection signal obtained by the insulation resistance deterioration detection unit and a value of the voltage measured by the power supply voltage measurement unit (for example, see PTL 2).

For example, there is known a detection device configured to detect insulation deterioration of a motor connected to a motor drive device that includes a converter unit including a rectifier circuit for rectifying an AC power supply, a smoothing capacitor for smoothing an output from the rectifier circuit, and a plurality of inverter units for converting a direct current from the converter unit into an alternate current to individually drive a plurality of motors, the detection device including: one first switch configured to be electrically connected when insulation deterioration is detected to ground one end of the smoothing capacitor; one voltage detection unit configured to measure a voltage across both ends of the smoothing capacitor; a plurality of second switches configured to be electrically connected when insulation deterioration is detected to connect the other end of the smoothing capacitor individually to windings of the plurality of motors; a plurality of electric current detection units configured to detect a discharge current of the smoothing capacitor that flows through an insulation resistor of each of the plurality of motors when the first switch and the plurality of second switches are electrically connected; and a plurality of insulation resistance calculation units configured to calculate an insulation resistance of each of the plurality of motors from a voltage detected by the voltage detection unit and an electric current detected by each of the plurality of electric current detection units, wherein the one first switch and the one voltage detection unit are provided in the converter unit, the plurality of second switches, the plurality of electric current detection units, and the plurality of insulation resistance calculation units are provided in the plurality of inverter units, the detection device further including a communication means for transmitting the value of the voltage detected by the one voltage detection unit and a signal for notifying a timing for turning on the one first switch from the converter unit to the plurality of inverter units, wherein in each of the plurality of inverter units, connection by the second switch, detecting of the electric current by the electric current detection unit, and calculation of the insulation resistance by the insulation resistance calculation unit are performed at the same time at the same timing (for example, see PTL 3).

For example, there is known a motor drive device including: a rectifier circuit configured to rectify an AC voltage supplied from an AC power supply via a first switch into a DC voltage; a power supply unit configured to smooth the DC voltage rectified by the rectifier circuit with a capacitor; an inverter unit configured to convert the DC voltage that has been smoothed by the power supply unit into an AC voltage by a switching operation of a semiconductor switching device to drive a motor; an electric current detection unit configured to measure a value of an electric current flowing through a resistor, one end of which is connected to a coil of the motor and the other end of which is connected to one terminal of the capacitor; a voltage detection unit configured to measure a value of a voltage across both ends of the capacitor; a second switch configured to ground the other terminal of the capacitor; and an insulation resistance detection unit configured to detect an insulation resistance of the motor, using two sets of values of the electric currents and the voltages measured when operation of the motor is stopped with the first switch being turned OFF in two conditions, i.e., the second switch being turned OFF and the second switch being turned ON, the insulation resistance being a resistance between the coil of the motor and the ground (for example, see PTL 4).

For example, there is known a motor controller including a first power supply unit, a first switch capable of cutting off supply of electrical power from the first power supply unit, a direct current supply unit that outputs the electrical power from the first power supply unit to a bus, a capacitor connected to the bus, and a switching element that converts the direct current supplied to the bus into an alternate current and controls driving of a motor, the motor controller further including: a second power supply unit that is connected to the bus at one end thereof and grounded at the other end via a second switch; an electric current detection unit that detects an electric current flowing through the bus that connects a winding of the motor and the second power supply unit; an insulation resistance calculation unit that calculates an insulation resistance value of the motor based on values of electric current detected by the electric current detection unit in cases where the second switch is open and closed when the electrical power is cut off by the first switch, a value of a voltage across the capacitor, and a value of a voltage of the second power supply unit (for example, see PTL 5).

### PATENT LITERATURE

[PTL 1] JP 4554501B
[PTL 2] JP 5832578B
[PTL 3] JP 4565036B
[PTL 4] JP 5788538B
[PTL 5] JP 2021-018163A

### SUMMARY OF THE INVENTION

It is highly important to eliminate causes of errors caused by components constituting an insulation resistance value detection circuit in accurate detecting of an insulation resistance value. In detecting of the insulation resistance value, it is also preferable to reduce burden of an operator. Thus, it is desired to provide a technique for easily detecting the insulation resistance value of the motor in a motor drive device with high degree of accuracy.

According to one aspect of the present disclosure, a first switch configured to open/close an electrical path from an AC power supply; a power supply unit configured to rectify an AC voltage supplied from the AC power supply via the first switch in a closed state into a DC voltage with a rectifier circuit, smooth the rectified DC voltage with a capacitor, and output the resultant DC voltage; a motor drive amplifier unit configured to convert the DC voltage input from the power supply unit via a DC input part into an AC voltage for driving a motor using switching elements in an upper arm and a lower arm and supply the AC voltage to the motor via an AC output part; a first voltage measurement unit configured to obtain a measured value of a voltage of the power supply unit; an insulation resistance value detection unit including a second switch configured to connect one end of the capacitor to the ground in the closed state and disconnect the one end of the capacitor from the ground in an open state, a measuring resistor placed between one terminal in the DC input part to which the other end of the capacitor is connected and one terminal in the AC output part to which a motor coil of the motor is connected, a second voltage measurement unit configured to obtain a measured value of a voltage between terminals of the measuring resistor, and a calculation unit configured to calculate an insulation resistance value of the motor, using at least the measured value of the voltage between the terminals of the measuring resistor obtained by the second voltage measurement unit; a voltage estimation unit configured to calculate an estimated value of the voltage between the terminals of the measuring resistor, in a condition where a DC voltage from a DC power supply different from the power supply unit is applied between the one terminal in the DC input part and the one terminal in the AC output part, when a second closed circuit including the DC power supply and the measuring resistor is formed by setting the first switch and the second switch in the open state and by setting the switching elements of the motor drive amplifier unit in an OFF state, based on the value of the DC voltage from the DC power supply and a resistance value of the measuring resistor; and an error detection unit configured to detect a measurement error of the second voltage measurement unit using the measured value of the voltage between the terminals of the measuring resistor, which has been obtained by the second voltage measurement unit when the second closed circuit is formed, and the estimated value of the voltage between the terminals of the measuring resistor, which has been calculated by the voltage estimation unit are included; and the calculation unit calculates the insulation resistance value of the motor based on the measured value of the voltage of the power supply unit obtained by the first voltage measurement unit, the measured value of the voltage between the terminals of the measuring resistor obtained by the second voltage measurement unit, the measurement error, and the resistance value of the measuring resistor, the measured value of the voltage of the power supply unit and the measured value of the voltage between the terminals of the measuring resistor being obtained when a first closed circuit is formed by setting the first switch in the open state and setting the second switch in the closed state, the first closed circuit including the second switch, the capacitor, the measuring resistor, the motor coil, and the ground.

According to one aspect of the present disclosure, a motor drive device can be achieved, the motor drive device being configured to easily detect the insulation resistance value of the motor with high degree of accuracy.

### BRIEF DESCRIPTION OF DRAWINGS

FIG. 1 is a diagram illustrating a motor drive device according to one embodiment of the present disclosure.

FIG. 2 is a diagram describing a DC power supply connected to the motor drive device according to one embodiment of the present disclosure when detecting a measurement error of a second voltage measurement unit in the motor drive device.

FIG. 3 is a diagram describing a second closed circuit that is formed when detecting a measurement error of the second voltage measurement unit in the motor drive device according to one embodiment of the present disclosure.

FIG. 4 is a flowchart illustrating operation sequences in measurement error detection processing of a first mode in the motor drive device according to one embodiment of the present disclosure.

FIG. 5 is a flowchart illustrating operation sequences in the measurement error detection processing of a second mode in the motor drive device according to one embodiment of the present disclosure.

FIG. 6 is a diagram describing a first closed circuit that is formed when executing processing of detecting an insulation resistance value by an insulation resistance value detection unit in the motor drive device according to one embodiment of the present disclosure.

FIG. 7 is a flowchart illustrating operation sequences in the processing of detecting the insulation resistance value by the insulation resistance value detection unit in the motor drive device according to one embodiment of the present disclosure.

FIG. 8 is an illustration of a second switch 31 in a closed state that is omitted.

FIG. 9 is a perspective view of a servo amplifier serving as a motor drive amplifier unit in the motor drive device according to one embodiment of the present disclosure.

FIG. 10 is a front view of a servo amplifier serving as a motor drive amplifier unit in the motor drive device according to one embodiment of the present disclosure.

FIG. 11 is an exploded perspective view of a servo amplifier serving as a motor drive amplifier unit in the motor drive device according to one embodiment of the present disclosure.

FIG. 12 is a schematic diagram illustrating a first circuit board and a second circuit board in a servo amplifier serving as a motor drive amplifier unit in the motor drive device according to one embodiment of the present disclosure.

### DETAILED DESCRIPTION OF EMBODIMENTS OF THE INVENTION

With reference to the drawings, a motor drive device configured to calculate an insulation resistance value of a motor will be described below. In each drawing, the same kind of members are denoted by the same kind of reference signs. To facilitate understanding, these drawings use different scales as appropriate. An embodiment illustrated in the drawings is one example for implementing the present disclosure, and the present disclosure is not limited to the illustrated embodiment.

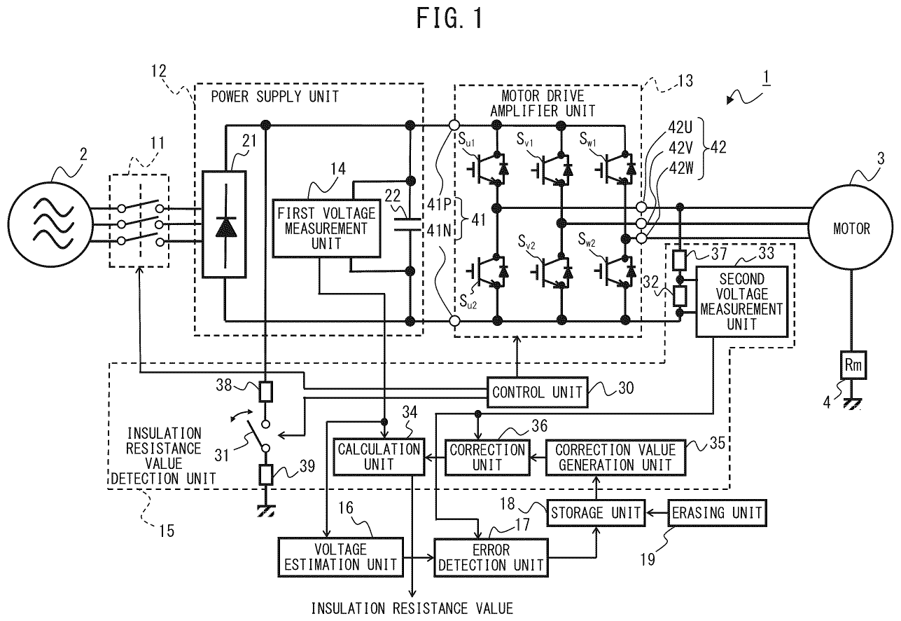

FIG. 1 is a diagram illustrating a motor drive device according to one embodiment of the present disclosure.

As an example, a case is illustrated in which a motor 3 is controlled by a motor drive device 1 connected to an AC power supply 2. In the present embodiment, a type of the motor 3 is not particularly limited, and it may be an induction motor or a synchronous motor. The number of phases of the AC power supply 2 and the motor 3 is not particularly limited the present embodiment, and the number of phases may be, for example, three phases or a single phase. Examples of machinery provided with the motor 3 include, for example, machine tools, robots, forming machines, injection molding machines, industrial machinery, various types of electrical appliances, trains, automobiles, and aircraft. Examples of the AC power supply 2 include a three-phase 400 V AC power supply, a three-phase 200 V AC power supply, a three-phase 600 V AC power supply, and a single-phase 100 V AC power supply. In the illustrated example, both of the AC power supply 2 and the motor 3 are three-phase.

There is an insulation resistor 4 between a motor coil (winding) of the motor 3 and the ground. A resistance value of the insulation resistor 4, i.e., an insulation resistance value Rm [Ω] is infinite if it does not deteriorate and gradually decreases, for example, based on infinity to several megohms, several hundred-kilo ohms, or the like, as it is deteriorated. The motor drive device 1 according to one embodiment of the present disclosure has a function of detecting the insulation resistance value Rm [Ω] of the motor 3.

As illustrated in FIG. 1, the motor drive device 1 according to one embodiment of the present disclosure includes: a first switch 11; a power supply unit 12; a motor drive amplifier unit 13; a first voltage measurement unit 14; an insulation resistance value detection unit 15; a voltage estimation unit 16; an error detection unit 17; a storage unit 18; and an erasing unit 19.

The first switch 11 opens/closes an electrical path between an AC power supply 2 and a rectifier circuit 21 in the power supply unit 12. Opening/closing of the electrical path by the first switch 11 is controlled, for example, by a control unit 30 in the insulation resistance value detection unit 15; alternatively, it may be controlled by any given control unit (not illustrated) including an arithmetic processing unit, the control unit being provided externally to the insulation resistance value detection unit 15. The first switch 11 is constructed from, for example, a magnetic contactor. A closed state for the electrical path between the AC power supply 2 and the rectifier circuit 21 in the power supply unit 12 is achieved by closing a contact of the first switch 11, the first switch 11 being a magnetic contactor, while an open state for the electrical path between the AC power supply 2 and the rectifier circuit 21 in the power supply unit 12 is achieved by opening the contact of the first switch 11, the first switch 11 being a magnetic contactor. It should be noted that the first switch 11 may be, for example, a relay or a semiconductor switching device instead of a magnetic contactor as long as it can open/close the electrical path from the AC power supply 2.

The power supply unit 12 is connected to the motor drive amplifier unit 13 via a DC link. A “DC link” refers to a portion of a circuit that electrically connects a DC output terminal of the power supply unit 12 to a DC input terminal of the motor drive amplifier unit 13, and it may be referred to as a “DC link unit”, a “direct current link”, a “direct current link unit”, a “direct current intermediate circuit”, or the like.

The power supply unit 12 includes the rectifier circuit 21 and a capacitor 22, rectifies an AC voltage supplied from the AC power supply 2 via the first switch 11 in the open state into a DC voltage with the rectifier circuit 21, smooths the rectified DC voltage with the capacitor 22, and outputs the resultant DC voltage.

The rectifier circuit 21 in the power supply unit 12 may be, for example, a diode rectifier circuit, a 120-degree conduction type rectifier circuit, or a rectifier circuit including switching elements inside employing a PWM switching control method as long as it can convert an AC voltage into a DC voltage. When the AC power supply 2 is a three-phase AC power supply, the rectifier circuit 21 is constructed as a three-phase bridge circuit; when the AC power supply 2 is a single-phase AC power supply, the rectifier circuit 21 is constructed as a single-phase bridge circuit. When the rectifier circuit 21 is a rectifier circuit employing a PWM switching control method, the rectifier circuit 21 is constructed from a bridge circuit including switching elements and diodes connected in antiparallel to the switching elements. In this case, examples of the switching elements include an IGBT, a thyristor, a GTO (gate turn-off thyristor), and a transistor although the type of the switching element itself does not limit the present embodiment and other types of switching elements may be used.

The capacitor 22 in the power supply unit 12 has a function of smoothing the DC voltage output by the rectifier circuit 21 and a function of accumulating the DC power in the DC link. The capacitor 22 may be also referred to as a smoothing capacitor or a DC link capacitor. Examples of the capacitor 22 include, for example, an electrolytic capacitor and a film capacitor.

The first voltage measurement unit 14 is connected to the positive and negative terminals of the capacitor 22. The first voltage measurement unit 14 is a measuring circuit for obtaining a measured value of a (DC) voltage of the power supply unit 12, the voltage being applied to the capacitor 22.

The motor drive amplifier unit 13 includes an inverter constructed from a bridge circuit including a set of switching elements and diodes connected in antiparallel to the switching elements disposed in an upper arm and a lower arm. In the illustrated example, since the motor 3 is assumed to be a three-phase AC motor, the inverter in the motor drive amplifier unit 13 is constructed from a three-phase bridge circuit. It is assumed here that the switching elements in the upper arm and the lower arm of the U-phase are respectively Sᵤ₁ and Sᵤ₂, the switching elements in the upper arm and the lower arm of the V-phase are respectively Sᵥ₁ and Sᵥ₂, and the switching elements in the upper arm and the lower arm of the W-phase are respectively S_{w1} and S_{w2}.

The motor drive amplifier unit 13 also includes a DC input part 41 on the side of the DC link and an AC output part 42 on the side of the AC motor. A positive DC terminal 41P in the DC input part 41 is connected to a positive power line of the DC link while a negative DC terminal 41N in the DC input part 41 is connected to a negative power line of the DC link. A U-phase AC terminal 42U in the AC output part 42 is connected to a U-phase motor power line, a V-phase AC terminal 42V in the AC output part 42 is connected to a V-phase motor power line, and a W-phase AC terminal 42W in the AC output part 42 is connected to a W-phase motor power line. The U-phase motor power line, the V-phase motor power line, and the W-phase motor power line are respectively connected to a U-phase motor coil, a V-phase motor coil, and a W-phase motor coil of the motor 3.

The motor drive amplifier unit 13 performs power conversion operation in response to a PWM switching command from a higher-level controller (not illustrated) for controlling on-off operations of the switching elements in the upper arm and the lower arm. In other words, the motor drive amplifier unit 13 converts a DC voltage at the DC link, which has been input via the DC input part 41, into an AC voltage for driving the motor as a result of the on-off operations of the switching elements in the upper arm and the lower arm, and supplies the AC voltage to the motor 3 via the AC output part 42. In one embodiment of the present disclosure, on-off operations of the switching elements in the upper arm and the lower arm of the motor drive amplifier unit 13 are also controlled by the control unit 30 of the insulation resistance value detection unit 15, and details thereof will be described below.

The insulation resistance value detection unit 15 detects the insulation resistance value Rm [Ω] that is a resistance value of the insulation resistor 4 between the motor coil (winding) of the motor 3 and the ground. The insulation resistance value detection unit 15 includes: the control unit 30, a second switch 31, a measuring resistor 32, a second voltage measurement unit 33, a calculation unit 34, a correction value generation unit 35, and a correction unit 36. Detecting of the insulation resistance value Rm [Ω] of the insulation resistor 4 of the motor 3 by the insulation resistance value detection unit 15 is performed using various types of data with respect to a first closed circuit obtained by setting the first switch 11 in the open state, setting the second switch 31 in the closed state and setting all the switching elements in the motor drive amplifier unit 13 in the OFF state. The first closed circuit is a closed circuit for detecting the insulation resistance value and includes the second switch 31, the capacitor 22, the measuring resistor 32, the motor coil of the motor 3, and the ground.

One terminal of the second switch 31 in the insulation resistance value detection unit 15 is connected to a voltage-dividing resistor 38 while the other terminal of the second switch 31 is connected to a voltage-dividing resistor 39. One terminal of the voltage-dividing resistor 38 is connected to a positive power line that connects the rectifier circuit 21 to the capacitor 22 in the power supply unit 12. One terminal of the voltage-dividing resistor 39 is connected to the ground. Grounding is controlled by an open/close operation of the second switch 31; in other words, when the second switch 31 is in the closed state, a positive terminal of the capacitor 22 is connected to the ground, and when the second switch 31 is in the open state, one end of the capacitor is not connected to the ground. Opening/closing of the second switch 31 is controlled by the control unit 30. The second switch 31 is constructed from, for example, a relay, a semiconductor switching device, or a magnetic contactor.

The measuring resistor 32 is placed between a negative terminal of the capacitor 22 and the motor coil of the motor 3. More specifically, one terminal of the measuring resistor 32 is connected to the negative terminal of the capacitor 22 via the negative DC terminal 41N in the DC input part 41 of the motor drive amplifier unit 13. The other terminal of the measuring resistor 32 is connected, via a voltage-dividing resistor 37, to one of the motor power lines for the motor 3, i.e., the U-phase motor power line, the V-phase motor power line, or the W-phase motor power line. In the illustrated example, the other terminal of the measuring resistor 32 is connected, as an example, to the U-phase motor power line that connects the U-phase AC terminal 42U in the AC output part 42 of the motor drive amplifier unit 13 to the U-phase motor coil of the motor 3. The second voltage measurement unit 33 is a measuring circuit for obtaining a measured value of a voltage between the terminals (i.e., inter-terminal voltage) of the measuring resistor 32. For example, the measuring resistor 32 and the second voltage measurement unit 33 may be constructed from an isolated amplifier. The voltage-dividing resistor 37 is provided for adjusting an input voltage for the isolated amplifier within an appropriate range.

The correction value generation unit 35 generates a correction value based on a measurement error of the second voltage measurement unit 33 detected by the error detection unit 17 to be described below. The correction unit 36 corrects the measured value of the voltage between the terminals of the measuring resistor 32, which has been obtained by the second voltage measurement unit 33 when the first closed circuit is formed, using the correction value generated by the correction value generation unit 35, and generates a corrected value of the measured value of the voltage between the terminals of the measuring resistor 32. The corrected value of the measured value of the voltage between the terminals of the measuring resistor 32 generated by the correction unit 36 based on the measurement error of the second voltage measurement unit 33 is used by the calculation unit 34 for calculation of the insulation resistance value Rm [Ω] of the motor 3.

The calculation unit 34 calculates the insulation resistance value of the motor 3 using at least the measured value of the voltage between the terminals of the measuring resistor 32 obtained by the second voltage measurement unit 33 when the first closed circuit including the second switch 31, the capacitor 22, the measuring resistor 32, the motor coil of the motor 3, and the ground is formed. In other words, the calculation unit 34 calculates the insulation resistance value Rm [Ω] of the insulation resistor 4 of the motor 3 based on the measured value of the voltage of the power supply unit 12, which has been obtained by the first voltage measurement unit 14 when the first closed circuit is formed, the corrected value of the measured value of the voltage between the terminals of the measuring resistor 32 generated by the correction unit 36, and the resistance value of the measuring resistor 32. The processing of calculating the insulation resistance value by the calculation unit 34 will be described in detail below.

Detection of the measurement error of the second voltage measurement unit 33 is performed using various types of data with respect to a second closed circuit obtained in a condition where a DC voltage from a DC power supply different from the power supply unit 12 is applied between one terminal in the DC input part 41 (the negative DC terminal 41N in the illustrated example) and one terminal in the AC output part 42 (the U-phase AC terminal 42U in the illustrated example) by setting the first switch 11 and the second switch 31 in the open state and by switching all the switching elements in the upper arm or the lower arm of the motor drive amplifier unit 13 in the OFF state. The second closed circuit is a closed circuit for detecting an error and includes the DC power supply and the measuring resistor 32.

The voltage estimation unit 16 calculates an estimated value of the voltage between the terminals of the measuring resistor 32 according to a circuit equation with respect to the second closed circuit including the DC power supply and the measuring resistor 32, the circuit equation obtained in a condition where the DC voltage from the DC power supply different from the power supply unit 12 is applied between one terminal in the DC input part 41 (the negative DC terminal 41N in the illustrated example) and one terminal in the AC output part 42 (the U-phase AC terminal 42U in the illustrated example) by setting the first switch 11 and the second switch 31 in the open state and by switching all the switching elements in the upper arm or the lower arm of the motor drive amplifier unit 13 in the OFF state, based on the measured value of the voltage of the power supply unit 12, which has been obtained by the first voltage measurement unit 14, and the resistance value of the measuring resistor 32.

The error detection unit 17 detects an error between the measured value of the voltage between the terminals of the measuring resistor 32, which has been obtained by the second voltage measurement unit 33 when the second closed circuit is formed, and the estimated value of the voltage between the terminals of the measuring resistor 32, which has been calculated by the voltage estimation unit 16. The measurement error of the second voltage measurement unit 33 detected by the error detection unit 17 is used in correction value generation processing by the correction value generation unit 35. It should be noted that “the measured value of the voltage between the terminals of the measuring resistor 32, which has been obtained by the second voltage measurement unit 33”, which is used in measurement error detection processing by the error detection unit 17 is not a value corrected by the correction unit 36.

The storage unit 18 stores the measurement error of the second voltage measurement unit 33 detected by the error detection unit 17. The storage unit 18 may be, for example, configured using an electrically erasable and recordable non-volatile memory such as EEPROM (registered trademark) or high-speed readable/writable random access memory such as DRAM or SRAM. The measurement error stored in the storage unit 18 is used in the correction value generation processing by the correction value generation unit 35. The measurement error stored in the storage unit 18 may be erased by the erasing unit 19 in a predetermined case.

In the motor drive device 1, an arithmetic processing unit (processor) is provided. Examples of the arithmetic processing unit include an IC, an LSI, a CPU, an MPU, and a DSP. The arithmetic processing unit includes: the first voltage measurement unit 14, the control unit 30, the second voltage measurement unit 33, the calculation unit 34, the correction value generation unit 35, the correction unit 36, the voltage estimation unit 16, the error detection unit 17, and the erasing unit 19. Each of these units included in the arithmetic processing unit is a functional module achieved by, for example, a computer program executed by the processor. For example, when the first voltage measurement unit 14, the control unit 30, the second voltage measurement unit 33, the calculation unit 34, the correction value generation unit 35, the correction unit 36, the voltage estimation unit 16, the error detection unit 17, and the erasing unit 19 are built in the form of a computer program, functions of the respective units may be achieved by causing the arithmetic processing unit to operate in accordance with the computer program. The computer program for executing processing by the first voltage measurement unit 14, the control unit 30, the second voltage measurement unit 33, the calculation unit 34, the correction value generation unit 35, the correction unit 36, the voltage estimation unit 16, the error detection unit 17, and the erasing unit 19 may be recorded on and supplied in the form of a computer-readable recording medium, such as a semiconductor memory, a magnetic recording medium, or an optical recording medium. Alternatively, the functions of the first voltage measurement unit 14, the control unit 30, the second voltage measurement unit 33, the calculation unit 34, the correction value generation unit 35, the correction unit 36, the voltage estimation unit 16, the error detection unit 17, and the erasing unit 19 may be achieved by a semiconductor integrated circuit into which a computer program for achieving the functions of the respective units is written.

The insulation resistance value of the motor 3 detected by the insulation resistance value detection unit 15 is transmitted to a display unit (not illustrated), and the display unit displays “the insulation resistance value of the motor 3” to notify an operator of the value. Examples of the display unit include a stand-alone display device, a display device accompanying the motor drive device 1, a display device accompanying a higher-level controller (not illustrated), and a display device accompanying a personal computer or a mobile terminal. Alternatively, the insulation resistance value of the motor 3 detected by the insulation resistance value detection unit 15 may be transmitted, for example, to an alarm output unit (not illustrated), and the alarm output unit may output an alarm when the insulation resistance value of the motor 3 is less than a predetermined value. The alarm output from the alarm output unit is transmitted, for example, to a light-emitting device (not illustrated), such as an LED or a lamp, and the light-emitting device emits light upon receiving the alarm to notify the operator of “deterioration of the insulation resistor 4 of the motor 3”. In addition, the alarm output from the alarm output unit is transmitted, for example, to a sound device (not illustrated), and the sound device emits a sound of, for example, a speaker, a buzzer, a chime, or the like, upon receiving the alarm to notify the operator of “deterioration of the insulation resistor 4 of the motor 3”. With this operation, the operator can certainly and easily understand the deterioration of the insulation resistance value of the motor 3 or the insulation resistor 4 of the motor 3, and can easily take action such as replacing the motor 3 or dismounting and cleaning the motor 3.

Next, the detection of the measurement error of the second voltage measurement unit 33 is described in more detail.

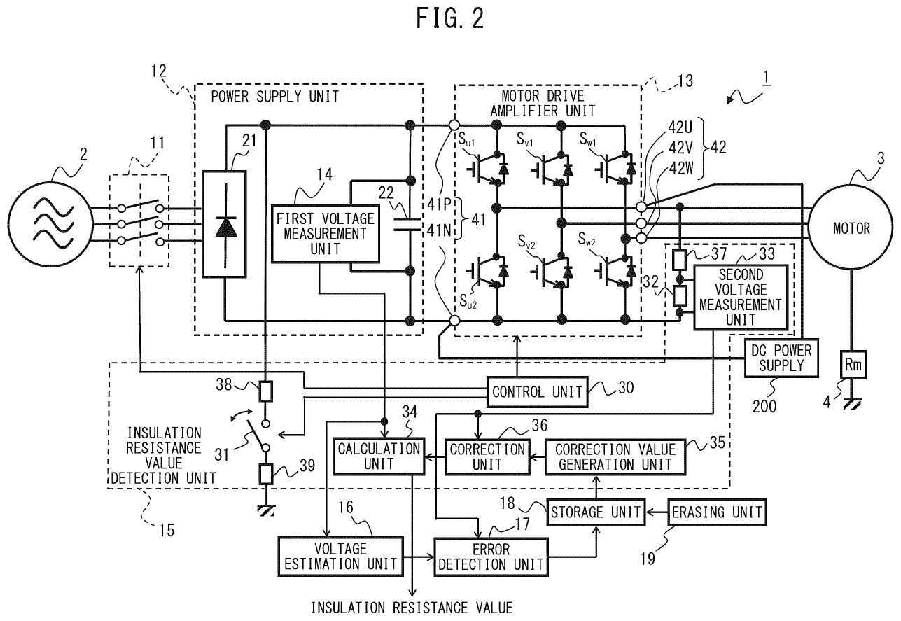

FIG. 2 is a diagram describing a DC power supply connected to the motor drive device according to one embodiment of the present disclosure when detecting the measurement error of the second voltage measurement unit. In order to detect the measurement error of the second voltage measurement unit 33, as illustrated in FIG. 2, the DC power supply 200 different from the power supply unit 12 is connected to apply a DC voltage between the negative DC terminal 41N in the DC input part 41 and one terminal in the AC output part 42. In the examples illustrated in FIG. 1 and FIG. 2, since the other terminal of the measuring resistor 32 is connected to the U-phase motor power line via the voltage-dividing resistor 37 and the U-phase AC terminal 42U in the AC output part 42 of the motor drive amplifier unit 13, the DC power supply 200 is connected between the negative DC terminal 41N in the DC input part 41 and the U-phase AC terminal 42U in the AC output part 42. When the other terminal of the measuring resistor 32 is connected to the V-phase motor power line via the voltage-dividing resistor 37 and the V-phase AC terminal 42V in the AC output part 42 of the motor drive amplifier unit 13, the DC power supply 200 is connected between the negative DC terminal 41N in the DC input part 41 and the V-phase AC terminal 42V in the AC output part 42. When the other terminal of the measuring resistor 32 is connected to the W-phase motor power line via the voltage-dividing resistor 37 and the W-phase AC terminal 42W in the AC output part 42 of the motor drive amplifier unit 13, the DC power supply 200 is connected between the negative DC terminal 41N in the DC input part 41 and the W-phase AC terminal 42W in the AC output part 42.

The DC power supply 200 is connected to one terminal in the DC input part 41 and one terminal in the AC output part 42 in the motor drive amplifier unit 13 in an electrically removable manner, specific examples of which are described as follows. For example, an operator may manually connect a portable battery serving as the DC power supply 200 to one terminal in the DC input part 41 and one terminal in the AC output part 42 in the motor drive amplifier unit 13. Alternatively, for example, a shipping inspection device including the DC power supply 200 is prepared in advance, and the shipping inspection device may be connected, at the time of shipping inspection of the motor drive device 1, to one terminal in the DC input part 41 and one terminal in the AC output part 42 in the motor drive amplifier unit 13. Alternatively, for example, the DC power supply 200 is installed in a main body of the motor drive amplifier unit 13 or a module adjacent to the motor drive amplifier unit 13, and electrical connection of the DC power supply 200 to one terminal in the DC input part 41 and one terminal in the AC output part 42 in the motor drive amplifier unit 13 may be configured to be switchable with an operation of a switch.

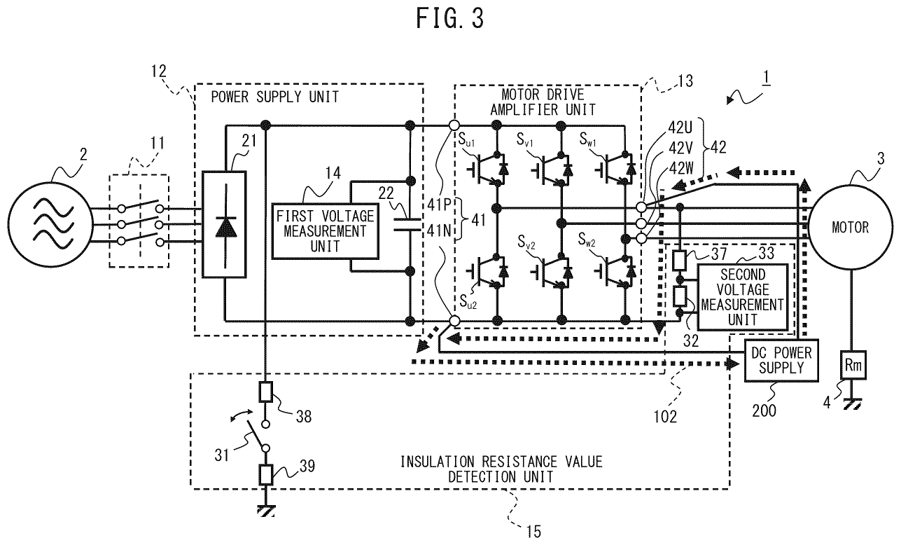

FIG. 3 is a diagram describing the second closed circuit that is formed when detecting the measurement error of the second voltage measurement unit in the motor drive device according to one embodiment of the present disclosure. In FIG. 3, illustrations of the control unit 30, the calculation unit 34, the correction value generation unit 35, the correction unit 36, the voltage estimation unit 16, the error detection unit 17, and the erasing unit 19 are omitted.

When detecting the measurement error of the second voltage measurement unit 33, the DC power supply 200 is connected between the negative DC terminal 41N in the DC input part 41 and the U-phase AC terminal 42U in the AC output part 42. In addition, the first switch 11 and the second switch 31 are set in the open state and all the switching elements in the upper arm or the lower arm of the motor drive amplifier unit 13 are set in the OFF state. With this operation, the second closed circuit 102 for detecting the measurement error, which is indicated in the figure with an arrow in a bold line, is formed.

When the second closed circuit 102 is formed, by using the value of the DC voltage of the DC power supply 200, the voltage between the terminals of the measuring resistor 32 can be estimated. Assuming that the resistance value of the measuring resistor 32 is Rb [Ω], the resistance value of the voltage-dividing resistor 37 is Ra [Ω], and the value of the DC voltage of the DC power supply 200 is Ve [V], an estimated value Vin1 [V] of the voltage between the terminals of the measuring resistor 32 when the second closed circuit 102 is formed can be calculated according to equation 1.

$$\begin{matrix}[ Math . 1 ] & \\ Vin 1 = Ve \times \frac{Rb}{Ra + Rb} & ( 1 )\end{matrix}$$

The voltage estimation unit 16 calculates the estimated value Vin1 [V] of the voltage between the terminals of the measuring resistor 32 when the second closed circuit 102 is formed, according to equation 1 using the value Ve [V] of the DC voltage of the DC power supply 200, the resistance value Rb [Ω] of the measuring resistor 32, and the resistance value Ra [Ω] of the voltage-dividing resistor 37. The resistance value Rb [Ω] of the measuring resistor 32 and the resistance value Ra [Ω] of the voltage-dividing resistor 37 are known, and, for example, nominal values of these components defined by the manufacturer may be used. The resistance value Rb [Ω] of the measuring resistor 32 and the resistance value Ra [Ω] of the voltage-dividing resistor 37 may be input in advance to the arithmetic processing unit constituting the voltage estimation unit 16 to be used in calculation of the estimated value Vin1 [V] of the voltage between the terminals of the measuring resistor 32 by the voltage estimation unit 16.

In addition, when the second closed circuit 102 is formed as described, a measured value Vin2 [V] of the voltage between the terminals of the measuring resistor 32 (actual measured value) can be obtained by the second voltage measurement unit 33.

When the second closed circuit 102 is formed, the estimated value Vin1 [V] of the voltage between the terminals of the measuring resistor 32 and the measured value (actual measured value) Vin2 [V] of the voltage between the terminals of the measuring resistor 32 are ideally identical. Actually, there is a measurement error between these values caused by variations and aging of components, i.e., the second voltage measurement unit 33, the measuring resistor 32, and the voltage-dividing resistor 37 that constitute the isolated amplifier. The measurement error contains an offset error and a gain error. Several modes of measurement error detection processing are recited here.

First, the measurement error detection processing of a first mode is described.

The measurement error detection processing of the first mode is for detecting only an offset error. In a condition where a DC voltage of the DC power supply 200 having a value Ve [V] is applied between the negative DC terminal 41N in the DC input part 41 and the U-phase AC terminal 42U in the AC output part 42, when the second closed circuit 102 is formed, an offset error ΔV [V] between the estimated value Vin1 [V] of the voltage between the terminals of the measuring resistor 32 and the measured value (actual measured value) Vin2 [V] of the voltage between the terminals of the measuring resistor 32 is given by equation 2.

$$\begin{matrix}[ Math . 2 ] & \\ Δ V = Vin 1 - Vin 2 & ( 2 )\end{matrix}$$

In the measurement error detection processing of the first mode, the error detection unit 17 detects the offset error ΔV [V], which is the measurement error, according to equation 2 using the measured value Vin2 [V] of the voltage between the terminals of the measuring resistor 32, which has been obtained by the second voltage measurement unit 33 when the second closed circuit 102 is formed, and the estimated value Vin1 [V] of the voltage between the terminals of the measuring resistor 32, which has been calculated by the voltage estimation unit 16. The offset error ΔV [V], which is the measurement error of the second voltage measurement unit 33 detected by the error detection unit 17, is stored in the storage unit 18.

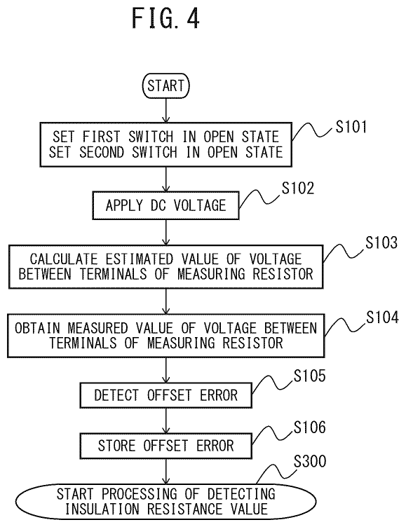

FIG. 4 is a flowchart illustrating operation sequences in the measurement error detection processing of the first mode in the motor drive device according to one embodiment of the present disclosure.

In the measurement error detection processing of the first mode, firstly, in step S101, the control unit 30 controls the first switch 11 and the second switch 31 to be in the open state. The control unit 30 also controls all the switching elements in the motor drive amplifier unit 13 to be in the OFF state.

In step S102, the DC power supply 200 is connected between the negative DC terminal 41N in the DC input part 41 and the U-phase AC terminal 42U in the AC output part 42, and the DC voltage Ve [V] is applied. With this operation, the second closed circuit 102 for detecting an error including the DC power supply 200 and the measuring resistor 32 is formed.

In step S103, the voltage estimation unit 16 calculates, when the second closed circuit 102 is formed, the estimated value Vin1 [V] of the voltage between the terminals of the measuring resistor 32 according to equation 1 using the value Ve [V] of the DC voltage of the DC power supply 200, the resistance value Rb [Ω] of the measuring resistor 32, and the resistance value Ra [Ω] of the voltage-dividing resistor 37.

In step S104, the second voltage measurement unit 33 obtains, when the second closed circuit 102 is formed, the measured value Vin2 [V] of the voltage between the terminals of the measuring resistor 32. The orders for performing steps S103 and S104 may be swapped.

In step S105, the error detection unit 17 detects, according to equation 2, the offset error ΔV [V] using the measured value Vin2 [V] of the voltage between the terminals of the measuring resistor 32, which has been obtained by the second voltage measurement unit 33 when the second closed circuit 102 is formed, and the estimated value Vin1 [V] of the voltage between the terminals of the measuring resistor 32, which has been calculated by the voltage estimation unit 16.

In step S106, the storage unit 18 stores the offset error ΔV [V] detected by the error detection unit 17. Then, the processing of detecting the insulation resistance to be described below is started in step S300.

Next, the measurement error detection processing of a second mode is described.

The measurement error detection processing of the second mode is for detecting both of the offset error and the gain error. Assuming that the gain error of the second voltage measurement unit 33 is “a” and the offset error of the second voltage measurement unit 33 is b [V], between the measured value Vin2 [V] of the voltage between the terminals of the measuring resistor 32, which has been obtained by the second voltage measurement unit 33 when the second closed circuit 102 is formed, and the estimated value Vin1 [V] of the voltage between the terminals of the measuring resistor 32, which has been calculated by the voltage estimation unit 16, a relationship as expressed by equation 3 holds.

$$\begin{matrix}[ Math . 3 ] & \\ Vin 2 = a \times V in 1 + b & ( 3 )\end{matrix}$$

In a condition where the second closed circuit 102 is formed, when the value Ve [V] of the DC voltage of the DC power supply 200 changes, the value of the estimated value Vin1 [V] of the measuring resistor 32 estimated by the voltage estimation unit 16 changes, and the measured value Vin2 [V] of the measuring resistor 32 obtained by the second voltage measurement unit 33 changes. Therefore, by applying two types of voltages between the negative DC terminal 41N in the DC input part 41 and the U-phase AC terminal 42U in the AC output part 42 as the value Ve of the DC voltage of the DC power supply 200, two types of relations based on equation 3 are obtained.

When a value of a first DC voltage of the DC power supply 200 is Ve1 [V], it is assumed that a first estimated value of the voltage between the terminals of the measuring resistor 32 that is estimated when the second closed circuit 102 is formed is Vin11 [V] and a first measured value of the voltage between the terminals of the measuring resistor 32 when the second closed circuit 102 is formed is Vin21 [V]. In this case, equation 4 and equation 5 hold.

$$\begin{matrix}[ Math . 4 ] & \\ Vin 11 = Ve 1 \times \frac{Rb}{Ra + Rb} & ( 4 )\end{matrix}$$

$$\begin{matrix}[ Math . 5 ] & \\ Vin 21 = a \times Vin 11 + b & ( 5 )\end{matrix}$$

When a value of a second DC voltage of the DC power supply 200 is Ve2 [V], it is assumed that a second estimated value of the voltage between the terminals of the measuring resistor 32 that is estimated when the second closed circuit 102 is formed is Vin12 [V] and a second measured value of the voltage between the terminals of the measuring resistor 32 when the second closed circuit 102 is formed is Vin22 [V]. It should be noted that the value Ve2 [V] of the second DC voltage of the DC power supply 200 is different from the value Ve1 [V] of the first DC voltage of the DC power supply 200. In this case, equation 6 and equation 7 hold.

$$\begin{matrix}[ Math . 6 ] & \\ Vin 12 = Ve 2 \times \frac{Rb}{Ra + Rb} & ( 6 )\end{matrix}$$

$$\begin{matrix}[ Math . 7 ] & \\ Vin 22 = a \times Vin 12 + b & ( 7 )\end{matrix}$$

In the measurement error detection processing of the second mode, the voltage estimation unit 16 calculates, when the second closed circuit 102 is formed, the first estimated value Vin11 [V] of the voltage between the terminals of the measuring resistor 32 according to equation 4 using the value Ve1 [V] of the first DC voltage from the DC power supply 200, the resistance value Rb [Ω] of the measuring resistor 32, and the resistance value Ra [Ω] of the voltage-dividing resistor 37. The voltage estimation unit 16 calculates, when the second closed circuit 102 is formed, the second estimated value Vin12 [V] of the voltage between the terminals of the measuring resistor 32 according to equation 6 using the value Ve2 [V] of the second DC voltage from the DC power supply 200, the resistance value Rb [Ω] of the measuring resistor 32, and the resistance value Ra [Ω] of the voltage-dividing resistor 37.

In the measurement error detection processing of the second mode, the second voltage measurement unit 33 obtains, when the second closed circuit 102 is formed, a first measured value Vin21 [V] of the voltage between the terminals of the measuring resistor 32 when the first DC voltage Ve1 [V] from the DC power supply 200 is applied, and obtains a second measured value Vin22 [V] of the voltage between the terminals of the measuring resistor 32 when the second DC voltage Ve2 [V] from the DC power supply 200 is applied.

By solving linear equations with two unknowns, i.e., equation 5 and equation 7, the gain error “a” given by equation 8 and the offset error b [V] given by equation 9 can be calculated.

$$\begin{matrix}[ Math . 8 ] & \\ a = \frac{Vin 21 - Vin 22}{Vin 11 - Vin 12} & ( 8 )\end{matrix}$$

$$\begin{matrix}[ Math . 9 ] & \\ b = \frac{Vin 11 \times Vin 22 - Vin 12 \times Vin 21}{Vin 11 - Vin 12} & ( 9 )\end{matrix}$$

In the measurement error detection processing of the second mode, the error detection unit 17 detects the gain error “a”, which is the measurement error, according to equation 8 and the offset error b [V], which is the measurement error, according to equation 9 using the first measured value Vin21 [V] of the voltage between the terminals of the measuring resistor 32 and the second measured value Vin22 [V] of the voltage between the terminals of the measuring resistor 32, which have been obtained by the second voltage measurement unit 33, and the first estimated value Vin11 [V] of the voltage between the terminals of the measuring resistor 32 and the second estimated value Vin12 [V] of the voltage between the terminals of the measuring resistor 32, which have been calculated by the voltage estimation unit 16. The gain error “a” and the offset error b [V], which are the measurement error of the second voltage measurement unit 33 detected by the error detection unit 17, are stored in the storage unit 18.

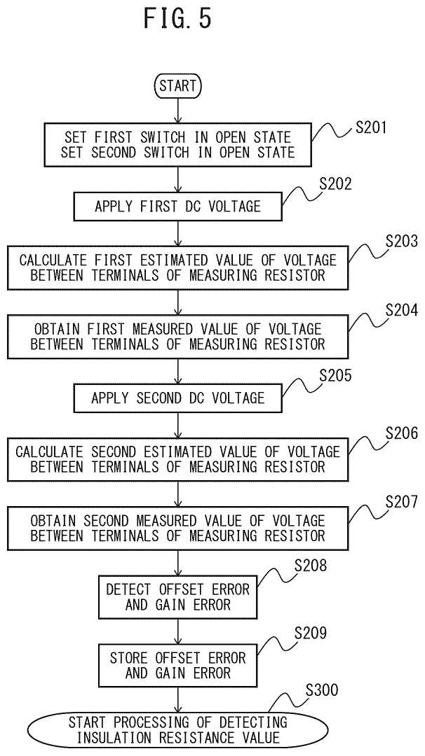

FIG. 5 is a flowchart illustrating operation sequences in the measurement error detection processing of the second mode in the motor drive device according to one embodiment of the present disclosure.

In the measurement error detection processing of the second mode, firstly, in step S201, the control unit 30 controls the first switch 11 and the second switch 31 to be in the open state. The control unit 30 also controls all the switching elements in the motor drive amplifier unit 13 to be in the OFF state.

In step S202, the DC power supply 200 is connected between the negative DC terminal 41N in the DC input part 41 and the U-phase AC terminal 42U in the AC output part 42, and the first DC voltage Ve1 [V] is applied. With this operation, the second closed circuit 102 for detecting an error including the DC power supply 200 that outputs the first DC voltage Ve1 [V] and the measuring resistor 32 is formed.

In step S203, the voltage estimation unit 16 calculates, when the second closed circuit 102 is formed, the first estimated value Vin11 [V] of the voltage between the terminals of the measuring resistor 32 according to equation 4 using the value Ve1 [V] of the first DC voltage of the DC power supply 200, the resistance value Rb [Ω] of the measuring resistor 32, and the resistance value Ra [Ω] of the voltage-dividing resistor 37.

In step S204, the second voltage measurement unit 33 obtains the first measured value Vin21 [V] of the voltage between the terminals of the measuring resistor 32 when the second closed circuit 102, to which the DC power supply 200 outputs the first DC voltage having the value Ve1 [V], is formed. The orders for performing steps S203 and S204 may be swapped.

In step S205, the DC power supply 200 is connected between the negative DC terminal 41N in the DC input part 41 and the U-phase AC terminal 42U in the AC output part 42, and the second DC voltage Ve2 [V] is applied. With this operation, the second closed circuit 102 for detecting an error including the DC power supply 200 that outputs the second DC voltage Ve2 [V] and the measuring resistor 32 is formed.

In step S206, the voltage estimation unit 16 calculates, when the second closed circuit 102 is formed, the second estimated value Vin12 [V] of the voltage between the terminals of the measuring resistor 32 according to equation 6 using the value Ve2 [V] of the second DC voltage of the DC power supply 200, the resistance value Rb [Ω] of the measuring resistor 32, and the resistance value Ra [Ω] of the voltage-dividing resistor 37.

In step S207, the second voltage measurement unit 33 obtains the second measured value Vin22 [V] of the voltage between the terminals of the measuring resistor 32 when the second closed circuit 102, to which the DC power supply 200 outputs the second DC voltage having the value Ve2 [V], is formed. The orders for performing steps S206 and S207 may be swapped.

In step S208, the error detection unit 17 detects the gain error “a”, which is the measurement error, according to equation 8 and the offset error b [V], which is the measurement error, according to equation 9 using the first measured value Vin21 [V] of the voltage between the terminals of the measuring resistor 32 and the second measured value Vin22 [V] of the voltage between the terminals of the measuring resistor 32, which have been obtained by the second voltage measurement unit 33, and the first estimated value Vin11 [V] of the voltage between the terminals of the measuring resistor 32 and the second estimated value Vin12 [V] of the voltage between the terminals of the measuring resistor 32, which have been calculated by the voltage estimation unit 16.

In step S209, the storage unit 18 stores the gain error “a” and the offset error b [V], which are the measurement error of the second voltage measurement unit 33 detected by the error detection unit 17. Then, the processing of detecting the insulation resistance to be described below is started in step S300.

Next, detecting of the insulation resistance value Rm [Ω] of the insulation resistor 4 of the motor 3 by the insulation resistance value detection unit 15 is described in more detail.

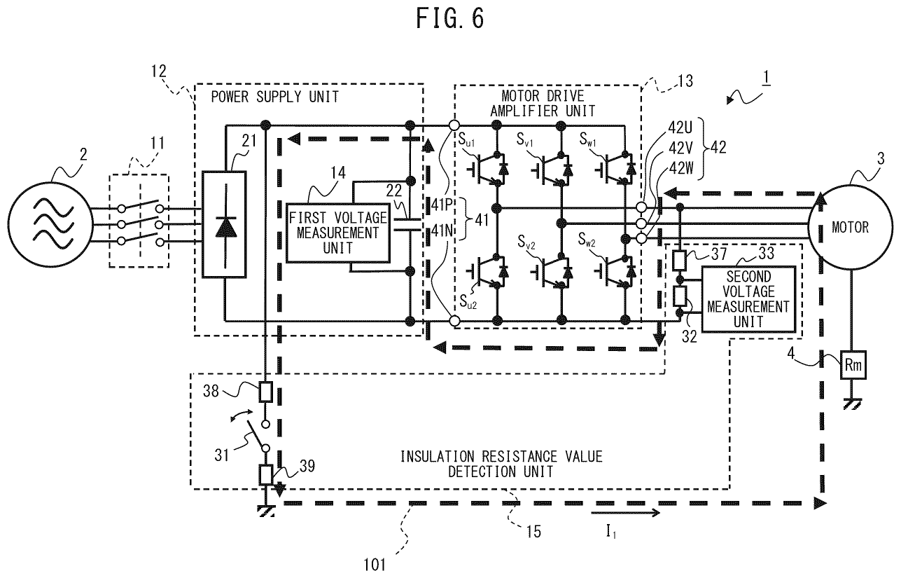

FIG. 6 is a diagram describing the first closed circuit that is formed when executing the processing of detecting the insulation resistance value by the insulation resistance value detection unit in the motor drive device according to one embodiment of the present disclosure. In FIG. 6, illustrations of the control unit 30, the calculation unit 34, the correction value generation unit 35, the correction unit 36, the voltage estimation unit 16, the error detection unit 17, and the erasing unit 19 are omitted.

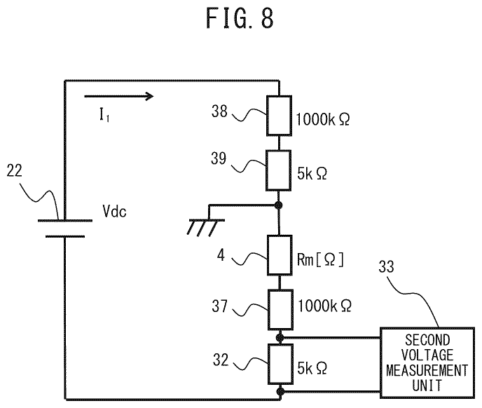

When the processing of detecting the insulation resistance value is executed by the insulation resistance value detection unit 15, firstly, the first switch 11 is set in the closed state, the second switch 31 is set in the open state, all the switching elements in the motor drive amplifier unit 13 are set in the OFF state, and charging the capacitor 22 with the power flowing into the capacitor 22 from the AC power supply 2 via the rectifier circuit 21 is performed. When charging of the capacitor 22 is completed, the first closed circuit 101 for detecting the insulation resistance value indicated in the figure with an arrow in a bold line is formed by setting the first switch 11 in the open state, setting the second switch 31 in the closed state and switching all the switching elements in the upper arm and the lower arm of the motor drive amplifier unit 13 in the OFF state. It should be noted that when driving of the motor 3 is already stopped after the motor 3 has been driven by the motor drive device 1, since the capacitor 22 is sufficiently charged, the first closed circuit 101 may be formed, with omitting “the processing of charging the capacitor 22 with the power flowing into the capacitor 22 from the AC power supply 2 via the rectifier circuit 21” in this case, by setting the first switch 11 in the open state, setting the second switch 31 in the closed state, and switching all the switching elements in the upper arm and the lower arm of the motor drive amplifier unit 13. FIG. 8 is a circuit diagram in which a part related to the first closed circuit is depicted. In FIG. 8, the illustration of the second switch 31 in the closed state is omitted. As illustrated in FIG. 6 and FIG. 8, the first closed circuit 101 includes the capacitor 22, the voltage-dividing resistor 38, the second switch 31 in the closed state, the voltage-dividing resistor 39, the insulation resistor 4 of the motor coil of the motor 3, the voltage-dividing resistor 37, and the measuring resistor 32.

When the first closed circuit 101 is formed, a leak current I₁ [A] that flows through the first closed circuit 101 can be calculated according to equation 10 based on the measured value (actual measured value) Vin3 [V] of the voltage between the terminals of the measuring resistor 32, which has been obtained by the second voltage measurement unit 33 and the resistance value Rb [Ω] of the measuring resistor 32.

$$\begin{matrix}[ Math . 10 ] & \\ {I}_{1} = \frac{Vin 3}{Rb} & ( 10 )\end{matrix}$$

When the first closed circuit 101 is formed, with the measured value Vdc [V] of the voltage of the power supply unit 12 (voltage across the capacitor 22) obtained by the first voltage measurement unit 14, the leak current I₁ [A] that flows through the first closed circuit 101, the resistance value Rb [Ω] of the measuring resistor 32, the resistance value Ra [Ω] of the voltage-dividing resistor 37, the resistance value Rc [Ω] of the voltage-dividing resistor 38, the resistance value Rd [Ω] of the voltage-dividing resistor 39, and the insulation resistance value Rm [Ω] of the insulation resistor 4 of the motor 3, a circuit equation as expressed by equation 11 holds.

$$\begin{matrix}[ Math . 11 ] & \\ Vdc = ( Rc + Rd + Rm + Ra + Rb ) \times {I}_{1} & ( 11 )\end{matrix}$$

By substituting equation 11 into equation 10 and transforming it, equation 12 is obtained.

$$\begin{matrix}[ Math . 12 ] & \\ Rm = \frac{Vdc}{Vin 3} \times Rb - ( Rc + Rd + Ra + Rb ) & ( 12 )\end{matrix}$$

According to equation 12, the insulation resistance value Rm [Ω] of the insulation resistor 4 of the motor 3 can be calculated. It should be noted that the output from the second voltage measurement unit 33 contains the measurement error caused by variations and aging of components, i.e., the second voltage measurement unit 33, the measuring resistor 32, and the voltage-dividing resistor 37 that constitute the isolated amplifier. The calculation unit 34 therefore calculates the insulation resistance value Rm [Ω] of the insulation resistor 4 of the motor 3 based on the measured value Vdc [V] of the voltage of the power supply unit 12 obtained by the first voltage measurement unit 14, the measured value Vin3 [V] of the voltage between the terminals of the measuring resistor 32 obtained by the second voltage measurement unit 33, the measurement error of the second voltage measurement unit 33, and the resistance value Rb [Ω] of the measuring resistor 32, wherein the measured value Vdc [V] and the measured value Vin3 [V] are obtained when the first closed circuit 101 is formed. Before performing this calculation, the measured value Vin3 [V] of the voltage between the terminals of the measuring resistor 32, which has been obtained by the second voltage measurement unit 33, is corrected using the measurement error of the second voltage measurement unit 33. Recited below are the processing of detecting the insulation resistance value of a first mode, the processing corresponding to the measurement error detection processing of the first mode in which only the offset error ΔV [V] is detected, and the processing of detecting the insulation resistance value of a second mode, the processing corresponding to the measurement error detection processing of the second mode in which the gain error “a” and the offset error b [V] are detected.

First, the processing of detecting the insulation resistance value of the first mode is described.

As described with reference to FIG. 3 and FIG. 4, in the measurement error detection processing of the first mode, the error detection unit 17 detects the offset error ΔV [V], which is the measurement error, according to equation 2 using the measured value Vin2 [V] of the voltage between the terminals of the measuring resistor 32, which has been obtained by the second voltage measurement unit 33 when the second closed circuit 102 is formed, and the estimated value Vin1 [V] of the voltage between the terminals of the measuring resistor 32, which has been calculated by the voltage estimation unit 16. When only the offset error ΔV is taken into account as the measurement error detected in the measurement error detection processing of the first mode, a value “−ΔV [V]” obtained by inverting the polarity of the error ΔV [V] is used as the correction value Vamend1 [V] for correcting the measured value Vin3 [V] of the voltage between the terminals of the measuring resistor 32 obtained by the second voltage measurement unit 33 when the first closed circuit 101 is formed. The correction value Vamend1 [V] is given by equation 13 using the offset error ΔV [V].

$$\begin{matrix}[ Math . 13 ] & \\ Vamend 1 = - Δ V & ( 13 )\end{matrix}$$

The correction value generation unit 35 generates the correction value Vamend [V] according to equation 13 using the offset error ΔV [V] that has been detected in the measurement error detection processing of the first mode.

By adding the correction value Vamend1 [V] for canceling out the offset error ΔV [V] to the measured value Vin3 [V] of the voltage between the terminals of the measuring resistor 32 obtained by the second voltage measurement unit 33 when the first closed circuit 101 is formed, a corrected value Vin41 [V] of the measured value of the voltage between the terminals of the measuring resistor 32 is obtained as expressed by equation 14.

$$\begin{matrix}[ Math . 14 ] & \\ Vin 41 = Vin 3 + V amend & ( 14 )\end{matrix}$$

The correction unit 36 corrects, according to equation 14, the measured value Vin3 [V] of the voltage between the terminals of the measuring resistor 32, which has been obtained by the second voltage measurement unit 33 when the first closed circuit 101 is formed, using the correction value Vamend1 [V] generated by the correction value generation unit 35, and generates the corrected value Vin41 [V] of the measured value of the voltage between the terminals of the measuring resistor 32.

In the processing of detecting the insulation resistance value of the first mode, the calculation unit 34 calculates the insulation resistance value Rm [Ω] of the insulation resistor 4 of the motor 3 according to equation 15, which is obtained by replacing the measured value Vin3 [V] of the voltage between the terminals of the measuring resistor 32 with the corrected value Vin41 [V] of the measured value of the voltage between the terminals of the measuring resistor 32 in equation 12.

$$\begin{matrix}[ Math . 15 ] & \\ Rm = \frac{Vdc}{Vin 41} \times Rb - ( Rc + Rd + Ra + Rb ) & ( 15 )\end{matrix}$$

An effect of the offset error ΔV [V] caused by variations and aging of components, i.e., the second voltage measurement unit 33, the measuring resistor 32, and the voltage-dividing resistor 37 that constitute the isolated amplifier on the accuracy in detecting of the insulation resistance value Rm [Ω] of the motor 3 is described with numerical examples.

For example, numerical examples are considered in which the resistance value Rc of the voltage-dividing resistor 38 is 1000 kΩ, the resistance value Rd of the voltage-dividing resistor 39 is 5 kΩ, the resistance value Rb of the measuring resistor 32 is 5 kΩ, the resistance value Ra of the voltage-dividing resistor 37 is 1000 kΩ, and the voltage Vdc of the power supply unit 12 (voltage across the capacitor 22) is 300 V.

When an actual value of the insulation resistance value Rm of the motor 3 is 1 MΩ, the voltage between the terminals of the measuring resistor 32 when the first closed circuit 101 is formed is, as a result of calculation according to equation 12, 498 mV. If an offset error ΔV of 10 mV is contained in the measured value Vin3 of the voltage between the terminals of the measuring resistor 32 obtained by the second voltage measurement unit 33, i.e., 498 mV, a correct value of the measured value Vin3 of the voltage between the terminals of the measuring resistor 32 should be 488 mV; when recalculation is made by assigning 488 mV to Vin3 (Vin3=488 mV) in equation 12, the insulation resistance value Rm of the motor 3 is 1.06 MΩ, which is different from the actual value of the insulation resistance value Rm of the motor 3, i.e., 1 MΩ.

When an actual value of the insulation resistance value Rm of the motor 3 is 10 MΩ, the voltage between the terminals of the measuring resistor 32 when the first closed circuit 101 is formed is, as a result of calculation according to equation 12, 125 mV. If an offset error ΔV of 10 mV is contained in the measured value Vin3 of the voltage between the terminals of the measuring resistor 32 obtained by the second voltage measurement unit 33, i.e., 125 mV, a correct value of the measured value Vin3 of the voltage between the terminals of the measuring resistor 32 should be 115 mV; when recalculation is made by assigning 115 mV to Vin2 (Vin2=115 mV) in equation 12, the insulation resistance value Rm of the motor 3 is 11.03 MΩ, which is different from the actual value of the insulation resistance value Rm of the motor 3, i.e., 10 MΩ.

When an actual value of the insulation resistance value Rm of the motor 3 is 50 MΩ, the voltage between the terminals of the measuring resistor 32 when the first closed circuit 101 is formed is, as a result of calculation according to equation 12, 29 mV. If an offset error ΔV of 10 mV is contained in the measured value Vin3 of the voltage between the terminals of the measuring resistor 32 obtained by the second voltage measurement unit 33, i.e., 29 mV, a correct value of the measured value Vin3 of the voltage between the terminals of the measuring resistor 32 should be 19 mV; when recalculation is made by assigning 19 mV to Vin3 (Vin3=19 mV) in equation 12, the insulation resistance value Rm of the motor 3 is 76.94 MΩ, which is different from the actual value of the insulation resistance value Rm of the motor 3, i.e., 50 MΩ.

As indicated by the numerical examples described above, as the actual value of the insulation resistance value Rm [Ω] of the motor 3 is larger, the insulation resistance value of the motor 3 will contain a larger error when it is calculated in a condition where the offset error ΔV is contained in the measured value Vin3 of the voltage between the terminals of the measuring resistor 32 obtained by the second voltage measurement unit 33 when the first closed circuit 101 is formed. According to the processing of detecting the insulation resistance value of the first mode, the measured value Vin3 [V] of the voltage [V] between the terminals of the measuring resistor 32 obtained by the second voltage measurement unit 33 is corrected using the value “−ΔV [V]” obtained by inverting the polarity of the offset error ΔV as the correction value Vamend1 [V] and the insulation resistance value Rm [Ω] is calculated using the corrected value Vin41 [V] of the measured value of the voltage [V] between the terminals of the measuring resistor 32; therefore, the insulation resistance value Rm [Ω] of the motor 3 can be correctly detected.

Next, the processing of detecting the insulation resistance value of the second mode is described.

As described with reference to FIG. 3 and FIG. 5, in the measurement error detection processing of the second mode, the error detection unit 17 detects the gain error “a”, which is the measurement error, according to equation 8 and the offset error b [V], which is the measurement error, according to equation 9 using the first measured value Vin21 [V] of the voltage between the terminals of the measuring resistor 32 and the second measured value Vin22 [V] of the voltage between the terminals of the measuring resistor 32, which have been obtained by the second voltage measurement unit 33, and the first estimated value Vin11 [V] of the voltage between the terminals of the measuring resistor 32 and the second estimated value Vin12 [V] of the voltage between the terminals of the measuring resistor 32, which have been calculated by the voltage estimation unit 16. When the gain error “a” and the offset error b [V] are taken into account as the measurement error detected in the measurement error detection processing of the second mode, the measured value Vin3 [V] of the voltage between the terminals of the measuring resistor 32 obtained by the second voltage measurement unit 33 when the first closed circuit 101 is formed is corrected using a correction formula as expressed by equation 16, and a corrected value Vin42 [V] of the measured value of the voltage between the terminals of the measuring resistor 32 is generated.

$$\begin{matrix}[ Math . 16 ] & \\ Vin 42 = \frac{Vin 3 - b}{a} & ( 16 )\end{matrix}$$

The correction value generation unit 35 generates, according to equation 16, the correction value (in other words, the correction formula as expressed by equation 16) using the gain error “a” and the offset error b [V], which have been detected in the measurement error detection processing of the second mode.

The correction unit 36 corrects the measured value Vin3 [V] of the voltage between the terminals of the measuring resistor 32, which has been obtained by the second voltage measurement unit 33 when the first closed circuit 101 is formed, using the correction formula as expressed by equation 16 generated by the correction value generation unit 35, and generates the corrected value Vin42 [V] of the measured value of the voltage between the terminals of the measuring resistor 32.

In the processing of detecting the insulation resistance value of the second mode, the calculation unit 34 calculates the insulation resistance value Rm [Ω] of the insulation resistor 4 of the motor 3 according to equation 17, which is obtained by replacing the measured value Vin3 [V] of the voltage between the terminals of the measuring resistor 32 with the corrected value Vin42 [V] of the measured value of the voltage between the terminals of the measuring resistor 32 in equation 12.

$$\begin{matrix}[ Math . 17 ] & \\ Rm = \frac{Vdc}{Vin 42} \times Rb - ( Rc + Rd + Ra + Rb ) & ( 17 )\end{matrix}$$

A numerical example of the gain error “a” and the offset error b [V] calculated by the correction value generation unit 35 according to equation 16 is described.

For example, a numerical example is considered in which the resistance value Rc of the voltage-dividing resistor 38 is 1000 kΩ, the resistance value Rd of the voltage-dividing resistor 39 is 5 kΩ, the resistance value Rb of the measuring resistor 32 is 5 kΩ, the resistance value Ra of the voltage-dividing resistor 37 is 1000 kΩ, the first measured value V22 of the of the measuring resistor 32 when the DC power supply 200 outputs the first DC voltage of 100V is 511 mV, and the second measured value V22 of the of the measuring resistor 32 when the DC power supply 200 outputs the second DC voltage of 90V is 460 m V.

When the DC power supply 200 outputs the first DC voltage of 100 V, the first estimated value V12 of the measuring resistor 32 is 498 mV according to equation 6. When the DC power supply 200 outputs the second DC voltage of 90 V, the second estimated value V12 of the measuring resistor 32 is 448 mV according to equation 6. When these numerical values are substituted in equation 8 and equation 9, the gain error “a” is 1.02 and the offset error b is 3 mV.

Since the offset error is more dominant than the gain error in the measurement error of the second voltage measurement unit 33, the insulation resistance value Rm [Ω] of the motor 3 can be detected with high degree of accuracy with the processing of detecting the insulation resistance value of the first mode in which only the offset error is taken into account; however, the insulation resistance value Rm [Ω] of the motor 3 can be detected with higher degree of accuracy with the processing of detecting the insulation resistance value of the second mode in which both of the gain error and the offset error are taken into account.

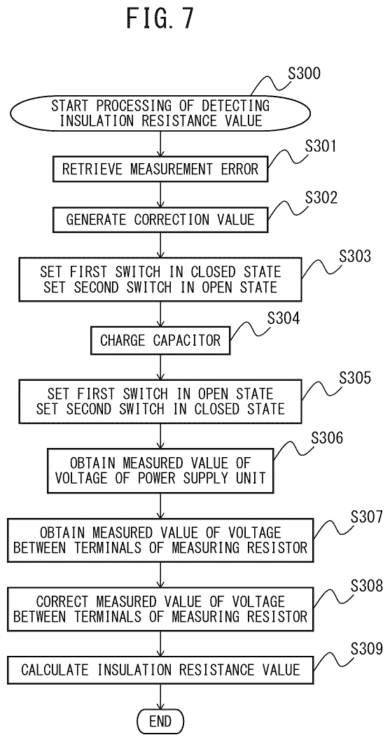

FIG. 7 is a flowchart illustrating operation sequences in the processing of detecting the insulation resistance value by the insulation resistance value detection unit in the motor drive device according to one embodiment of the present disclosure. The flowchart illustrated in FIG. 7 may be applied to both of the processing of detecting the insulation resistance value of the first mode and the processing of detecting the insulation resistance value of the second mode. Before starting the processing of detecting the insulation resistance value in step S300, the measurement error is already stored in the storage unit 18 by completing the measurement error detection processing of the first mode illustrated in FIG. 4 or the measurement error detection processing of the second mode illustrated in FIG. 5.

In step S301, the correction value generation unit 35 retrieves the measurement error that has been stored from the storage unit 18.

In step S302, the correction value generation unit 35 generates the correction value based on the measurement error.

In step S303, the control unit 30 controls the first switch 11 to be in the closed state and controls the second switch 31 to be in the open state. The control unit 30 also controls all the switching elements in the motor drive amplifier unit 13 to be in the OFF state. With this operation, in step S304, the capacitor 22 is charged with the electrical power flowing into the capacitor 22 from the AC power supply 2 via the rectifier circuit 21. The charging status of the capacitor 22 is monitored by the control unit 30 via the first voltage measurement unit 14. It should be noted that when driving of the motor 3 is already stopped after the motor 3 has been driven by the motor drive device 1, since the capacitor 22 is sufficiently charged, step S304 may be omitted.

When charging of the capacitor 22 is completed, in step S305, the control unit 30 controls the first switch 11 to be in the open state and controls the second switch 31 to be in the closed state. The control unit 30 also sets all the switching elements in the upper arm and the lower arm of the motor drive amplifier unit 13 in the OFF state. As a result, the first closed circuit 101 for detecting the insulation resistance value is formed.

In step S306, the first voltage measurement unit 14 obtains the measured value of the voltage of the power supply unit 12 (voltage across the capacitor 22).

In step S307, the second voltage measurement unit 33 obtains the measured value Vin3 [V] of the voltage between the terminals of the measuring resistor 32 when the first closed circuit 101 is formed.

In step S308, the correction unit 36 corrects the measured value Vin3 [V] of the voltage between the terminals of the measuring resistor 32, which has been obtained by the second voltage measurement unit 33 when the first closed circuit 101 is formed using the correction value generated by the correction value generation unit 35, and generates the corrected value of the measured value of the voltage between the terminals of the measuring resistor 32. When only the offset error ΔV [V] is detected with the measurement error detection processing of the first mode illustrated in FIG. 4, the correction unit 36 corrects, according to equation 14, the measured value Vin3 [V] of the voltage between the terminals of the measuring resistor 32, which has been obtained by the second voltage measurement unit 33 when the first closed circuit 101 is formed, using the correction value Vamend1 [V] generated by the correction value generation unit 35, and generates the corrected value Vin41 [V] of the measured value of the voltage between the terminals of the measuring resistor 32. When both of the gain error “a” and the offset error b [V] are detected with the measurement error detection processing of the second mode illustrated in FIG. 5, the correction unit 36 corrects the measured value Vin3 [V] of the voltage between the terminals of the measuring resistor 32, which has been obtained by the second voltage measurement unit 33 when the first closed circuit 101 is formed, using the correction formula as expressed by equation 16 generated by the correction value generation unit 35, and generates the corrected value Vin42 [V] of the measured value of the voltage between the terminals of the measuring resistor 32.

In step S309, the calculation unit 34 calculates the insulation resistance value Rm [Ω] of the insulation resistor 4 of the motor 3 based on the measured value of the voltage of the power supply unit 12, which has been obtained by the first voltage measurement unit 14 when the first closed circuit is formed 101, the corrected value of the measured value of the voltage between the terminals of the measuring resistor 32 generated by the correction unit 36, and the resistance value of the measuring resistor 32. More specifically, in the processing of detecting the insulation resistance value of the first mode, the calculation unit 34 calculates the insulation resistance value Rm [Ω] of the insulation resistor 4 of the motor 3 according to equation 15. The calculation unit 34 calculates the insulation resistance value Rm [Ω] of the insulation resistor 4 of the motor 3 according to equation 17.

Next, a specific example of the motor drive amplifier unit 13 is described. Examples of the motor drive amplifier unit 13 include, for example, a servo amplifier.

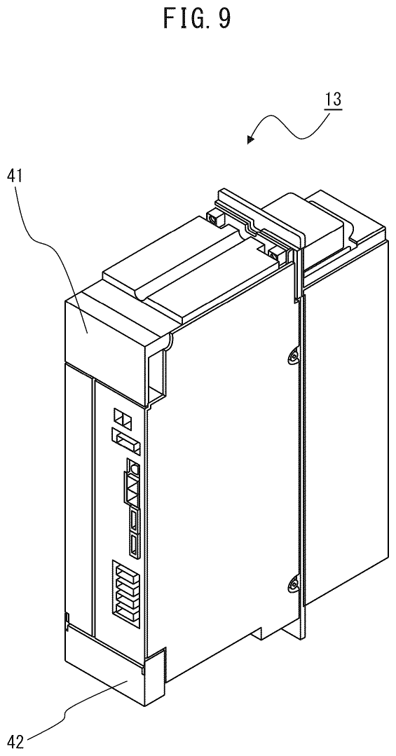

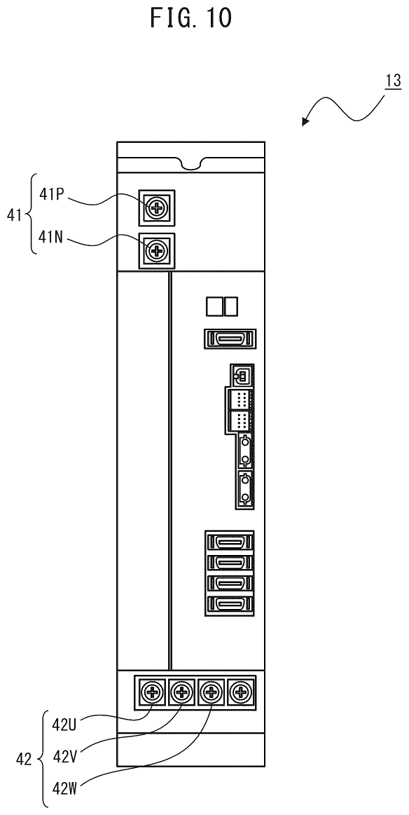

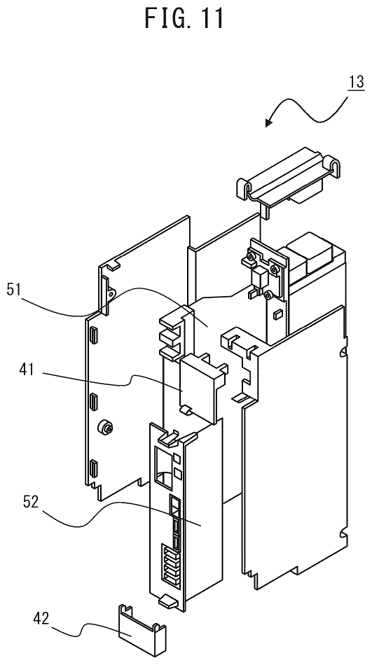

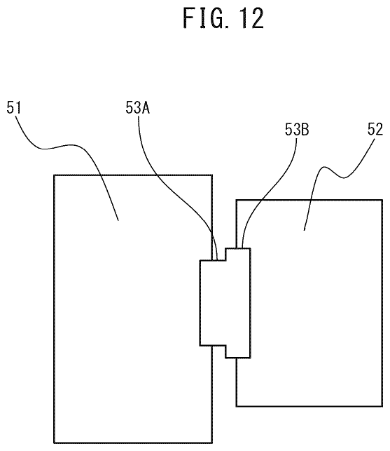

FIG. 9 is a perspective view of a servo amplifier serving as a motor drive amplifier unit in the motor drive device according to one embodiment of the present disclosure. FIG. 10 is a front view of a servo amplifier serving as a motor drive amplifier unit in the motor drive device according to one embodiment of the present disclosure. FIG. 11 is an exploded perspective view of a servo amplifier serving as a motor drive amplifier unit in the motor drive device according to one embodiment of the present disclosure. FIG. 12 is a schematic diagram illustrating a first circuit board and a second circuit board in a servo amplifier serving as a motor drive amplifier unit in the motor drive device according to one embodiment of the present disclosure.

In an enclosure of the servo amplifier serving as the motor drive amplifier unit 13, the DC input part 41 and the AC output part 42 are provided. The DC input part 41 includes the positive DC terminal 41P and the negative DC terminal 41N. The AC output part 42 includes the U-phase AC terminal 42U, the V-phase AC terminal 42V, and the W-phase AC terminal 42W. Thus, in the enclosure of the servo amplifier, the DC input part 41 and the AC output part 42 are provided, which facilitates connecting the DC power supply 200 from the outside of the servo amplifier. For example, at the time of shipping inspection or maintenance of the motor drive device 1, the measurement error detection processing can be executed by connecting the DC power supply 200. An EEPROM (registered trademark) provided in the servo amplifier serving as the motor drive amplifier unit 13 may be used as the storage unit 18.

In the servo amplifier serving as the motor drive amplifier unit 13, a plurality of circuit boards on which various components, the arithmetic processing unit, and wirings are mounted are provided. Conventionally, when some kind of failure occurs in the motor drive amplifier unit 13, only the circuit board in which a failure has occurred is replaced, and other circuit boards are reused. In one embodiment of the present disclosure, of the plurality of circuit boards provided in the servo amplifier serving as the motor drive amplifier unit 13, on a first circuit board 51 serving as a power PCB, a main circuit of the inverter, an arithmetic processing unit by which the insulation resistance value detection unit 15 and the erasing unit 19 are built, and the storage unit 18 are provided. On a second circuit board 52 serving as a PCB for control, an arithmetic processing unit by which the error detection unit 17 and the voltage estimation unit 16 are included are built. The first circuit board 51 and the second circuit board 52 are connected in an electrically and mechanically removable manner via a connector 53A provided on the first circuit board and a connector 53B provided on the second circuit board.

When a component other than the first circuit board 51 is replaced, for example, to deal with a failure or the like, although causes of errors of the second voltage measurement unit 33 in the insulation resistance value detection unit 15 mounted on the first circuit board do not change, the storage unit 18 in which the measurement error is stored is still mounted on the first circuit board 51, which allows the measurement error stored in the storage unit 18 to be used in the processing of detecting the insulation resistance value as is. Therefore, the measurement error of the second voltage measurement unit 33 does not need to be remeasured, which reduces burden of an operator, and the processing of detecting the insulation resistance value may be easily achieved with high degree of accuracy in a short time.

In contrast, when a component on the first circuit board 51, especially a component related to the insulation resistance value detection unit 15, is replaced, for example, to deal with a failure or the like, the measurement error stored in the storage unit 18 cannot be used in the processing of detecting the insulation resistance value in which the insulation resistance value detection unit 15 after replacement is used. In this case, the operator operates the erasing unit 19 via, for example, an input device and erases the measurement error stored in the storage unit 18. Then, the measurement error detection processing is performed again with respect to the insulation resistance value detection unit 15 after replacement to detect the measurement error of the second voltage measurement unit 33 in the insulation resistance value detection unit 15, and the measurement error is stored in the storage unit 18. With this operation, the processing of detecting the insulation resistance value may be performed with high degree of accuracy again thereafter. As described above, the motor drive device 1 according to one embodiment of the present disclosure calculates the insulation resistance value Rm [Ω] of the motor 3 based on the measurement error caused by variations and aging of components, i.e., the second voltage measurement unit 33, the measuring resistor 32, and the voltage-dividing resistor 37, therefore, the motor drive device can correctly detect the insulation resistance value Rm [Ω] of the motor 3. In addition, the magnitude of the DC voltage output by the DC power supply 200 just needs to be large enough to allow measurement of the measurement error of the second voltage measurement unit 33: this prevents application of large voltage to the motor power line, and it is safe.

### REFERENCE SIGNS LIST

1 Motor drive device
2 AC power supply
3 Motor
4 Insulation resistor
11 First switch
12 Power supply unit
13 Motor drive amplifier unit
14 First voltage measurement unit
15 Insulation resistance value detection unit
16 Voltage estimation unit
17 Error detection unit
18 Storage unit
19 Erasing unit
21 Rectifier circuit
22 Capacitor
30 Control unit
31 Second switch
32 Measuring resistor
33 Second voltage measurement unit
34 Calculation unit
35 Correction value generation unit
36 Correction unit
37, 38, 39 Voltage-dividing resistor
41 DC input part
41P Positive DC terminal
41N Negative DC terminal
42 AC output part
42U U-phase AC terminal
42V V-phase AC terminal
42W W-phase AC terminal
51 First circuit board
52 Second circuit board
53A, 53B Connector
101 First closed circuit
102 Second closed circuit
200 DC power supply

1. A motor drive device, comprising:
a first switch configured to open/close an electrical path from an AC power supply;
a power supply unit configured to rectify an AC voltage supplied from the AC power supply via the first switch in a closed state into a DC voltage with a rectifier circuit, smooth the rectified DC voltage with a capacitor, and output the resultant DC voltage;
a motor drive amplifier unit configured to convert the DC voltage input from the power supply unit via a DC input part into an AC voltage for driving a motor using switching elements in an upper arm and a lower arm and supply the AC voltage to the motor via an AC output part;
a first voltage measurement unit configured to obtain a measured value of a voltage of the power supply unit;
an insulation resistance value detection unit including a second switch configured to connect one end of the capacitor to the ground in the closed state and disconnect the one end of the capacitor from the ground in an open state, a measuring resistor placed between one terminal in the DC input part to which the other end of the capacitor is connected and one terminal in the AC output part to which a motor coil of the motor is connected, a second voltage measurement unit configured to obtain a measured value of a voltage between terminals of the measuring resistor, and a calculation unit configured to calculate an insulation resistance value of the motor, using at least the measured value of the voltage between the terminals of the measuring resistor, which has been obtained by the second voltage measurement unit;
a voltage estimation unit configured to calculate an estimated value of the voltage between the terminals of the measuring resistor, in a condition where a DC voltage from a DC power supply different from the power supply unit is applied between the one terminal in the DC input part and the one terminal in the AC output part, when a second closed circuit including the DC power supply and the measuring resistor is formed by setting the first switch and the second switch in the open state and by setting the switching elements of the motor drive amplifier unit in an OFF state, based on the value of the DC voltage from the DC power supply and a resistance value of the measuring resistor; and
an error detection unit configured to detect a measurement error of the second voltage measurement unit using the measured value of the voltage between the terminals of the measuring resistor, which has been obtained by the second voltage measurement unit when the second closed circuit is formed, and the estimated value of the voltage between the terminals of the measuring resistor, which has been calculated by the voltage estimation unit,
wherein the calculation unit calculates the insulation resistance value of the motor based on the measured value of the voltage of the power supply unit obtained by the first voltage measurement unit, the measured value of the voltage between the terminals of the measuring resistor obtained by the second voltage measurement unit, the measurement error, and the resistance value of the measuring resistor, the measured value of the voltage of the power supply unit and the measured value of the voltage between the terminals of the measuring resistor being obtained when a first closed circuit is formed by setting the first switch in the open state and setting the second switch in the closed state, the first closed circuit including the second switch, the capacitor, the measuring resistor, the motor coil, and the ground.

2. The motor drive device according to claim 1, wherein the insulation resistance value detection unit includes:
a correction value generation unit configured to generate a correction value based on a measurement error; and
a correction unit configured to correct the measured value of the voltage between the terminals of the measuring resistor, which has been obtained by the second voltage measurement unit when the first closed circuit is formed, based on the correction value, and to output a corrected value of the measured value of the voltage between the terminals of the measuring resistor,
wherein the calculation unit calculates, the insulation resistance value of the motor based on the measured value of the voltage of the power supply unit, which has been obtained by the first voltage measurement unit when the first closed circuit is formed, the corrected value of the measured value of the voltage between the terminals of the measuring resistor output from the correction unit, and the resistance value of the measuring resistor.

3. The motor drive device according to claim 2,
wherein the error detection unit detects an offset error, which is the measurement error, using the measured value of the voltage between the terminals of the measuring resistor, which has been obtained by the second voltage measurement unit when the second closed circuit is formed, and the estimated value of the voltage between the terminals of the measuring resistor, which has been calculated by the voltage estimation unit, and
wherein the correction value generation unit generates the correction value based on the offset error.

4. The motor drive device according to claim 2, wherein
the voltage estimation unit calculates, when the second closed circuit is formed, a first estimated value of the voltage between the terminals of the measuring resistor based on a value of a first DC voltage from the DC power supply and the resistance value of the measuring resistor, and calculates a second estimated value of the voltage between the terminals of the measuring resistor based on a value of a second DC voltage from the DC power supply, which is different from the value of the first DC voltage, and the resistance value of the measuring resistor,
the second voltage measurement unit obtains, when the second closed circuit is formed, a first measured value of the voltage between the terminals of the measuring resistor when the first DC voltage from the DC power supply is applied, and obtains a second measured value of the voltage between the terminals of the measuring resistor when the second DC voltage from the DC power supply is applied,
the error detection unit detects an offset error and a gain error, both of which are the measurement error, using the first measured value of the voltage between the terminals of the measuring resistor and the second measured value of the voltage between the terminals of the measuring resistor, which have been obtained by the second voltage measurement unit, and the first estimated value of the voltage between the terminals of the measuring resistor and the second estimated value of the voltage between the terminals of the measuring resistor, which have been calculated by the voltage estimation unit, and
the correction value generation unit generates the correction value based on the offset error and the gain error.

5. The motor drive device according to claim 2, comprising a storage unit configured to store the measurement error detected by the error detection unit,
wherein the correction value generation unit generates the correction value based on the measurement error stored in the storage unit.

6. The motor drive device according to claim 5, comprising:
a first circuit board on which at least, the insulation resistance value detection unit and the storage unit are provided; and
a second circuit board that is connected to the first circuit board in an electrically and mechanically removable manner and on which at least the error detection unit is provided.

7. The motor drive device according to claim 6, comprising an erasing unit configured to erase the measurement error stored in the storage unit.

8. The motor drive device according claim 1, wherein the DC power supply is connected to the one terminal in the DC input part and the one terminal in the AC output part in an electrically removable manner.
